(19) United States
(12) Patent Application Publication
(10) Pub. No.: US 2011/0268941 A1
(43) Pub. Date: Nov. 3, 2011

(54) PROCESS FOR MANUFACTURING SUBSTRATES PROVIDED WITH A MULTILAYER HAVING THERMAL PROPERTIES,IN PARTICULAR FOR PRODUCING HEATED GLAZING UNITS

(75) Inventors: Klaus Fischer, Alsdorf (DE); Robert Drese, Aachen (DE); Ariane Blanchard, Aachen (DE); Sebastian Janzyk, Herzogenrath (DE)

(73) Assignee: SAINT-GOBAIN GLASS FRANCE, Courbevoie (FR)

(21) Appl. No.: 13/121,688

(22) PCT Filed: Sep. 30, 2009
(86) PCT No.: PCT/FR2009/051854

§ 371 Date: Jul. 20, 2011

(30) Foreign Application Priority Data
Sep. 30, 2008 (FR) 0856575

(51) Int. Cl. B32B 7/02; C23C 14/14; C23C 14/08; C23C 14/34; C23C 14/06

(52) U.S. Cl. 428/213; 204/192.1

(57) ABSTRACT

A process for manufacturing at least one substrate, especially transparent glass substrates, each provided with a thin-film multilayer comprising an alternation of “n” metallic functional layers especially of functional layers based on silver or a metal alloy containing silver, and of “(n+1)” antireflection coatings, with n being an integer ≧3, each antireflection coating comprising at least one antireflection layer, so that each functional layer is positioned between two antireflection coatings, said thin-film multilayer being deposited by a vacuum technique, said multilayer being such that the thicknesses of two functional layers at least are different and the thicknesses of the functional layers have a symmetry within the multilayer relative to the center of the multilayer.

The invention relates to the manufacture of transparent substrates especially that are made of a rigid mineral material such as glass, said substrates being coated with a thin-film multilayer comprising several functional layers that can act on solar radiation and/or infrared radiation of long wavelength.

The invention relates more particularly to the manufacture of substrates, especially transparent glass substrates, each provided with a thin-film multilayer comprising an alternation of “n” metallic functional layers, especially of functional layers based on silver or on a metal alloy containing silver, and of “(n+1)” antireflection coatings, with n being an integer ≧3, so that each functional layer is positioned between two antireflection coatings. Each coating comprises at least one antireflection layer and each coating being, preferably, composed of a plurality of layers, at least one layer, or even each layer, of which is an antireflection layer.

The invention relates more particularly to the use of such substrates for manufacturing thermal insulation and/or solar protection glazing units. These glazing units may equally be intended for equipping both buildings and vehicles, especially with a view to reducing air-conditioning load and/or preventing excess overheating (glazing called “solar controlled” glazing) and/or reducing the amount of energy dissipated to the outside (glazing called “low-E” or “low-emissivity” glazing) brought about by the ever increasing use of glazed surfaces in buildings and vehicle passenger compartments.

These substrates may in particular be integrated into electronic devices and the multilayer may then act as an electrode for the conduction of a current (illuminating device, display device, voltaic panel, electrochromic glazing, etc.) or may be integrated into glazing units having particular functionalities, such as for example heated glazing units, and in particular heated windshields for vehicles.

Within the sense of the present invention, a multilayer having several functional layers is understood to mean a multilayer comprising at least three functional layers.

Multilayers having several functional layers are known.

These multilayers are generally deposited using a deposition machine which functions continuously (at the very least during an industrial production cycle) on substrates which, themselves, are not continuous and in general have, in the glass industry, a width of around 3 meters and a length of around 6 meters.

In this type of multilayer, each functional layer is positioned between two antireflection coatings each comprising, in general, several antireflection layers which are each made of a material of nitride type and especially silicon nitride or aluminum nitride and/or of oxide type. From an optical point of view, the purpose of these coatings which flank the functional layer is to “antireflect” this functional layer.

A very thin blocker coating is however interposed sometimes between one or each antireflection coating and an adjacent functional layer, the blocker coating positioned beneath the functional layer in the direction of the substrate and the blocker coating positioned on the functional layer on the opposite side from the substrate protects this layer from any degradation during the deposition of the upper antireflection coating and during an optional high-temperature heat treatment of the bending and/or toughening type.

Multilayers having several functional layers are known from the prior art, for example from International Patent Application No. WO 2005/051858.

In the multilayers having three or four functional layers presented in that document, the thicknesses of all the functional layers are substantially identical, that is to say that the thickness of the first functional layer, closest to the substrate, is substantially identical to the thickness of the second functional layer which is substantially identical to the thickness of the third functional layer, or even which is substantially identical to the thickness of the fourth functional layer when there is a fourth functional layer.

That document furthermore presents an example, example 14, in which the thickness of the first functional layer, the closest to the substrate, is less than the thickness of the second functional layer which is itself less than the thickness of the third functional layer, according to the teaching of European Patent Application No. EP 645 352.

The manufacture, on an industrial scale, of multilayers of this type having several functional layers (at least three functional layers) is complex. The tolerance for the difference in thicknesses of the functional layers relative to the theoretical thicknesses of these layers within the multilayer deposited on a substrate and the tolerance from one substrate to the next is relatively low since the functional layers can be deposited with great precision, including over the entire deposition thickness (in general of around 3 meters).

On the other hand, the tolerance for the difference in thicknesses of the antireflection layers within antireflection coatings of the multilayer deposited on a substrate and also this tolerance from one substrate coated with the multilayer to the next is relatively large in proportion, despite all the care taken during the deposition of these antireflection layers.

This is especially true for the antireflection layers deposited by a reactive process and especially by a chemical vapor deposition (CVD) process or by a reactive sputtering deposition process (reactive magnetron sputtering in an atmosphere containing nitrogen and/or oxygen with a view to forming, respectively, a nitride and/or an oxide).

It is found that the industrially acceptable tolerance for the deposition of these antireflection layers may lead to the production of substrates or substrate parts that do not have the desired optical characteristics or that have acceptable but slightly different optical characteristics, this difference being perceptible to the human eye.

Indeed, in regard to the number of antireflection layers in the multilayer (at least 4 and, for example, around ten for a multilayer having three functional layers, or even more still; at least 5 and, for example, around a dozen for a multilayer having four functional layers, or even more still) the accumulated effect of the acceptable tolerances for each layer may in the end result in a total thickness of material of antireflection layer in the multilayer which cannot be optically overlooked.

When the problem is faced within a multilayer deposited on a substrate (industrially having a dimension of around 6 m×3 m) and when this problem is reproduced exactly in the same manner in all the substrates of the series, one solution then consists in cutting out the parts that have excessively large differences over all the substrates and in removing these parts. This however gives rise to a significant cost premium for the industrial manufacture.

When the problem is faced from one substrate to another substrate, one solution then consists in removing all the substrates which have excessively large differences compared to the reference. This however gives rise to an unacceptable cost premium.

However, this problem may have significant consequences.

Thus, it may arise that when two (or more still) vehicles of the same model each equipped with an athermic windshield each incorporating a substrate having several functional layers are placed side by side, (these windshields normally being identical as they are both supplied by the same glass manufacturer) the windshields have, in reality, from a same point of observation in space (and therefore along substantially the same angle of observation) different colors in external reflection.

These differences of color in external reflection of the two windshields are not obvious but can be observed by an attentive and practiced eye.

They can also, of course, be observed by color measurements using appropriate equipment.

This may be annoying insofar as a potential purchaser may be led to interpret—although it is not technically true—this difference in color in reflection of the windshields of the two vehicles as a difference in the efficiency of the energy reflection of the windshields. A feeling of unpredictable efficiency may thus be associated with the difference of color in reflection and this may be damaging to the valuation of the two vehicles.

A similar problem may also, of course, arise for a building facade or for a display screen facade or for a photovoltaic panel facade integrating several windows/screens/panels, several windows/screens/panels of which each incorporate a substrate having several functional layers.

The objective of the invention is to succeed in overcoming the drawbacks of the prior art, by developing a novel type of thin-film multilayer having several functional layers, the color in reflection of which on the substrate side (at least, or even on the multilayer side) observed along a given angle is substantially the same over the entire surface of the substrate, even though the thickness of at least one (and optionally several) antireflection layer(s) may vary along the length and/or the width of the substrate.

Another important objective is to provide a novel type of thin-film multilayer having several functional layers, the color in reflection of which on the substrate side (at least, or even on the multilayer side) observed along a given angle, is substantially the same from one substrate to the next, even though the thickness of at least one (and optionally several) antireflection layer(s) may vary from this substrate to this next substrate.

Another important objective is to provide a multilayer that has a low surface resistivity (and therefore a low emissivity), a high light transmission and a relatively neutral color, in particular in reflection on the side of the layers (but also on the opposite side: the “substrate side”), and that these properties are preferably kept within a limited range whether or not the multilayer undergoes one (or more) high-temperature heat treatment(s) of the bending and/or toughening and/or annealing type.

Another important objective is to provide a multilayer having several functional layers which has a low emissivity while having a low light reflection in the visible spectrum, and also an acceptable coloration, especially in reflection, in particular which is not in the red spectrum.

One subject of the invention is thus, in its broadest sense, a process for manufacturing substrates according to claim 1.

The present invention furthermore relates, according to claim 10, to a set of substrates which have been manufactured by the process according to the invention, and also, according to claim 11, to a set of glazing units, each glazing unit of which incorporates at least one substrate manufactured by the process according to the invention.

The dependent claims set out alternative embodiments.

The substrates, which are especially transparent glass substrates, are each provided with a thin-film multilayer comprising an alternation of “n” metallic functional layers, especially of functional layers based on silver or a metal alloy containing silver, and of “(n+1)” antireflection coatings, with n being an integer ≧3, each antireflection coating comprising at least one antireflection layer, so that each functional layer is positioned between two antireflection coatings.

According to the invention, on the one hand, the thin-film multilayers are deposited on the substrates by a vacuum technique of the sputtering, optionally magnetron sputtering type. The multilayers deposited on the substrates are such that the thicknesses of two functional layers at least are different and the thicknesses of the functional layers have a symmetry within the multilayer relative to the center of the multilayer.

According to the invention, on the other hand, the thicknesses of at least one antireflection layer of at least one antireflection coating of at least two thin-film multilayers of a set of substrates are different from one multilayer to the next and exhibit a variation between ±2.5% and ±20%, especially between ±2.5% and ±15% and the difference in color in reflection on the substrate side between the two substrates at 0° (ΔE₀*) is close to zero and the color in reflection on the substrate side between the two substrates at 60° (ΔE₆₀*) is close to zero.

Within the symmetrical system of the multilayers according to the invention, there are therefore at least two functional layers that have different thicknesses; however, the symmetry in the thickness of the functional layers within the multilayer makes it possible, completely surprisingly, to obtain a color in reflection in a limited range (or “color box”), even if the thickness of one (or of several) antireflection layer(s) varies(vary) within the multilayer along the length and/or the width of the carrier substrate or even if the thickness of one (or more) antireflection layer(s) varies(vary) from one multilayer deposited on one substrate to another multilayer (of normally identical composition) deposited on another substrate.

It is important to observe here that the symmetry which is the subject of the invention is not a central symmetry within the distribution of all the layers of the multilayer (taking into account the antireflection layer), but only a central symmetry within the distribution of the functional layers.

The two functional layers which have different thicknesses are, preferably, contiguous (separated by an antireflection coating).

Unless otherwise mentioned, the thicknesses mentioned in the present document are physical, or actual, thicknesses (and not optical thicknesses).

Furthermore, when a vertical position of a layer (e.g. beneath/on top of) is mentioned, this is always by considering that the carrier substrate is positioned horizontally, at the bottom, with the multilayer on top of it. When it is specified that a layer is deposited directly onto another layer, this means that there cannot be one (or more) layer(s) interposed between these two layers.

The antireflection layer which is at least included in each antireflection coating, as defined above, has an optical index measured at 550 nm between 1.8 and 2.5 including these values, or, preferably, between 1.9 and 2.3 including these values, that is to say an optical index that can be considered to be high.

When it is considered that the thicknesses of at least one antireflection layer of at least one antireflection coating of at least two thin-film multilayers of a set of substrates are different, this means that for two thin-film multilayers of the set, these multilayers have the same qualitative composition but the comparison of the thicknesses of the various antireflection layers of the two multilayers leads to the observation that two antireflection layers located at the same position in the two multilayers do not have the same thickness: the variation observed for one thickness relative to the other is between ±2.5% and ±20%, especially between ±2.5% and ±15%.

In one particular variant, the multilayer comprises three functional layers alternated with four antireflection coatings and the thicknesses of the functional layers are such that the thicknesses of the functional layers located at the two extremities of the multilayer are both identical but are different from the thickness of the central functional layer.

In this particular variant having three functional layers, the thickness of the functional layer at the center of the symmetry is, preferably, greater than the thickness of the two other functional layers furthest from the center of symmetry.

This principle can be applied generally to any multilayer having an odd number of functional layers alternated with an even number of antireflection coatings: the thicknesses of the functional layers located at the two extremities of the multilayer are both identical but are different from the thickness of the central functional layer and the thicknesses of intermediate functional layers that are located between the central functional layer and the two functional layers at the extremities are identical in pairs relative to the central functional layer.

According to this generalized principle having an odd number of functional layers, the thickness of the functional layer at the center of the symmetry is, preferably, greater than the thickness of the functional layers furthest from the center of symmetry. The thickness of the functional layers then preferably decreases from the center of the multilayer toward the two extremities of the multilayer.

In another particular variant, the multilayer comprises four functional layers alternated with five antireflection coatings and the thicknesses of the functional layers are such that the thicknesses of the two functional layers furthest from the center of symmetry are both identical and the thicknesses of the two functional layers nearest to the center of symmetry are both identical.

In this other particular variant having four functional layers, the thickness of the two functional layers closest to the center of symmetry is, preferably, greater than the thickness of the two other functional layers furthest from the center of symmetry.

However, in this other particular variant having four functional layers, the thickness of the two functional layers closest to the center of symmetry may be smaller than the thickness of the two other functional layers furthest from the center of symmetry.

This principle can be applied generally to any multilayer having an even number of functional layers alternated with an odd number of antireflection coatings: the thicknesses of the functional layers located at the two extremities of the multilayer are both identical and the thicknesses of the functional layers located at the center of the multilayer are both identical, while being different from the thicknesses of the functional layers located at the two extremities of the multilayer, and the thicknesses of the intermediate functional layers, which are located between the two central functional layers and the two functional layers at the extremities, are identical in pairs relative to the central symmetry.

According to this generalized principle having an even number of functional layers, the thickness of the two functional layers closest to the center of symmetry is, preferably, greater than the thickness of the two functional layers furthest from the center of symmetry. The thickness of the functional layers then preferably decreases from the center of the multilayer toward the two extremities of the multilayer.

However, it is also possible that the thickness of the two functional layers closest to the center of symmetry is smaller than the thickness of the two functional layers furthest from the center of symmetry. The thickness of the functional layers then preferably increases from the center of the multilayer toward the two extremities of the multilayer.

The thickness of each functional layer is, preferably, between 7 and 16 nm.

The multilayer according to the invention is a multilayer having a low surface resistivity so that its surface resistivity R in ohms per square is, preferably, less than or equal to 1 ohm per square before any heat treatment or a fortiori after an optional heat treatment of the bending, toughening or annealing type since such a treatment in general has the effect of reducing the surface resistivity.

Said antireflection coatings preferably each comprise at least one layer based on silicon nitride, optionally doped with the aid of at least one other element, such as aluminum.

In one very particular variant, the last layer of each antireflection coating subjacent to a functional layer is a wetting layer based on an oxide, especially based on zinc oxide, optionally doped with the aid of at least one other element, such as aluminum.

In this variant, at least one antireflection coating subjacent to a functional layer comprises, preferably, at least one non-crystalline smoothing layer made of a mixed oxide, said smoothing layer being in contact with a crystalline superjacent wetting layer.

The present invention furthermore relates to glazing units each incorporating at least one substrate manufactured according to the invention, this substrate being optionally combined with at least one other substrate and especially a multiple glazing unit of the double-glazing or triple-glazing or laminated-glazing type and in particular laminated glazing comprising means for the electrical connection of the thin-film multilayer in order to make it possible to produce a heated laminated glazing, said substrate bearing the multilayer possibly being curved and/or toughened.

The glazing units according to the invention incorporate at least the substrate carrying the multilayer manufactured according to the invention, optionally combined with at least one other substrate. Each substrate may be clear or tinted. At least one of the substrates may especially be made of bulk-tinted glass. The choice of coloration type will depend on the level of light transmission and/or on the colorimetric appearance that is/are desired for the glazing once its manufacture has been completed.

The glazing units according to the invention may have a laminated structure, especially combining at least two rigid substrates of the glass type with at least one sheet of thermoplastic polymer, in order to have a structure of the glass/thin-film multilayer/sheet(s)/glass type. The polymer may especially be based on polyvinyl butyral (PVB), ethylene/vinyl acetate (EVA), polyethylene terephthalate (PET) or polyvinyl chloride (PVC).

The glazing units may then have a structure of the type: glass/thin-film multilayer/polymer sheet(s)/glass.

The glazing units according to the invention are capable of undergoing a heat treatment without damaging the thin-film multilayer. They are therefore possibly curved and/or toughened.

The glazing may be curved and/or toughened when consisting of a single substrate, that provided with the multilayer. Such glazing is then referred to as “monolithic” glazing. When they are curved, especially for the purpose of making glazing units for vehicles, the thin-film multilayer is preferably on an at least partly non-planar face.

The glazing may also be a multiple glazing unit, especially a double-glazing unit, at least the substrate carrying the multilayer being able to be curved and/or toughened. It is preferable in a multiple glazing configuration for the multilayer to be placed so as to face the intermediate gas-filled space. In a laminated structure, the substrate carrying the multilayer may be in contact with the sheet of polymer.

The glazing may also be a triple-glazing unit composed of three sheets of glass separated in pairs by a gas-filled space. In one structure made of a triple-glazing unit, the substrate carrying the multilayer may be on face 2 and/or on face 5, when it is considered that the incident direction of the sunlight passes through the faces in increasing order of their number.

When the glazing is monolithic or is in the form of multiple glazing of the double-glazing, triple-glazing or laminated-glazing type, at least the substrate carrying the multilayer may be made of curved or toughened glass, this substrate possibly being curved or toughened before or after the deposition of the multilayer.

The present invention also relates to a set of substrates according to the invention or a set of glazing units according to the invention, the thicknesses of at least one antireflection layer of at least one antireflection coating of at least two thin-film multilayers of the set of substrates or of the set of glazing units being different and exhibiting a variation between ±2.5% and ±20%, especially between ±2.5% and ±15% and the difference in color in reflection on the substrate side between the two substrates or glazing units at 0° (ΔE₀*) being close to zero and the color in reflection on the substrate side between the two substrates or glazing units at 60° (ΔE₆₀*) being close to zero.

In this set, either all the substrates or glazing units have undergone one and the same heat treatment, or none has undergone the heat treatment.

It is not ruled out that the first layer or layers of the multilayer may be deposited by a technique other than a vacuum technique, for example by a thermal decomposition technique of pyrolysis type. However, the functional layers are necessarily deposited by a vacuum technique; this is why it is written here that the thin-film multilayers are deposited on their substrates by a vacuum technique.

The invention also relates to the use of the substrates manufactured according to the invention for producing transparent coatings that are heated by the Joule effect for heated glazing units or for producing transparent electrodes for electrochromic glazing units or for illumination devices or for display devices or for photovoltaic panels.

The substrates manufactured according to the invention may, in particular, be used for producing transparent heated coatings for heated glazing units or for producing transparent electrodes for electrochromic glazing units (these glazing units being monolithic or being multiple glazing units of the double-glazing or triple-glazing or laminated-glazing type) or for illumination devices or for display screens or for photovoltaic panels. (The term “transparent” should be understood here as meaning “non-opaque”).

The process according to the invention is more profitable than the previous processes because it makes it possible to increase the general manufacturing tolerance of the multilayers and makes it possible for substrate parts or entire substrates to be rendered acceptable, without it being necessary to improve the tolerances of the deposition thicknesses of each antireflection layer.

By virtue of the process according to the invention, it is possible to produce sets of heated glazing units or sets of electrochromic glazing units or sets of illumination devices or sets of display screens or sets of photovoltaic panels. In these sets, when components that constitute them are juxtaposed, it is not possible for the human eye to detect differences in appearance (and especially in color) even though the multilayers incorporated into these components are different and this difference normally results in a difference in appearance.

The details and advantageous features of the invention will emerge from the following non-limiting examples, illustrated by means of the appended figures that illustrate:

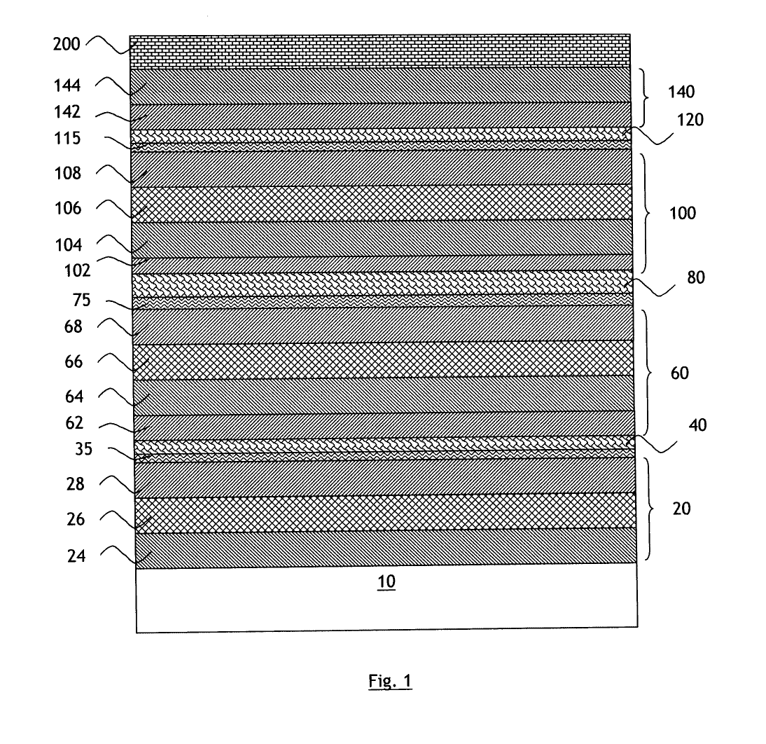

in FIG. 1, a multilayer having three functional layers, each functional layer being provided with an underblocker coating but not with an overblocker coating and the multilayer also being provided with an optional protective coating;

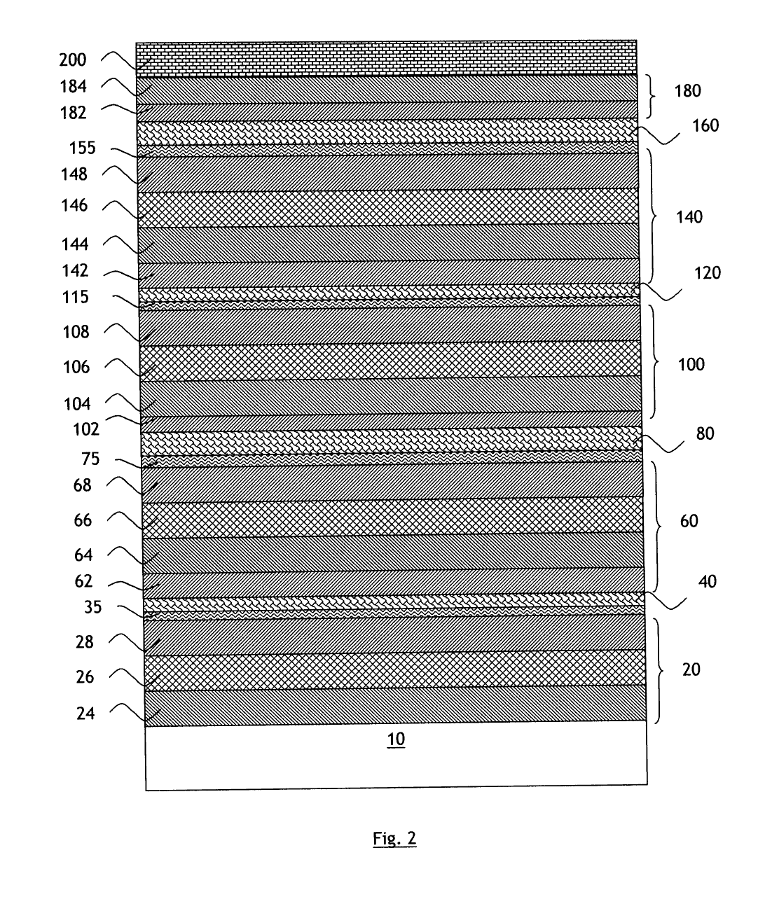

in FIG. 2, a multilayer having four functional layers, each functional layer being provided with an underblocker coating but not with an overblocker coating and the multilayer also being provided with an optional protective coating;

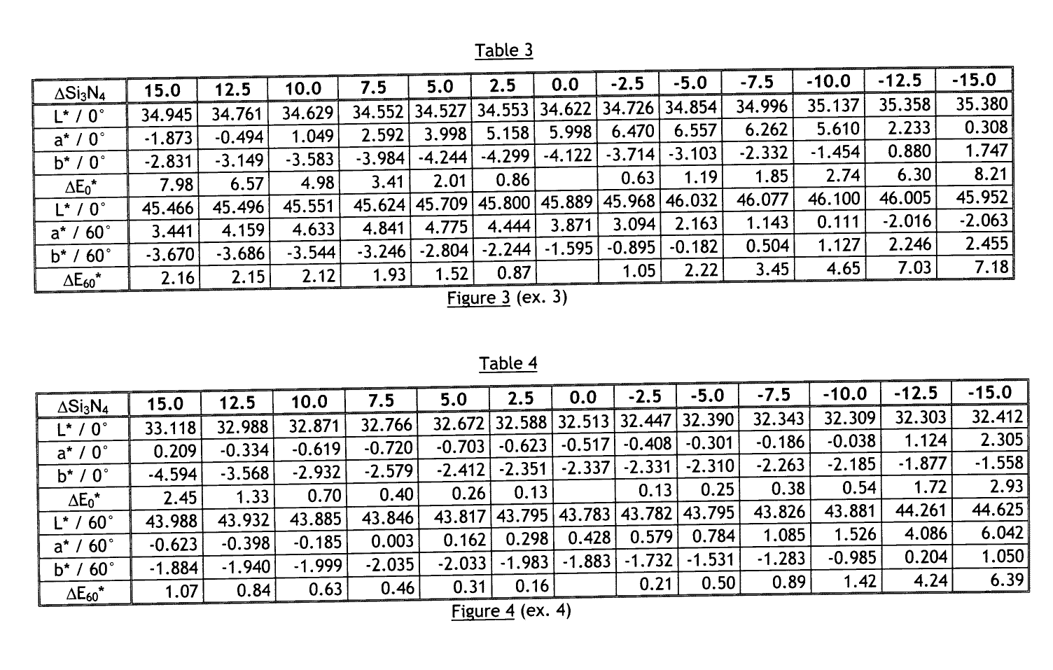

in FIG. 3, the optical characteristics for the examples 3;

in FIG. 4, the optical characteristics for the examples 4;

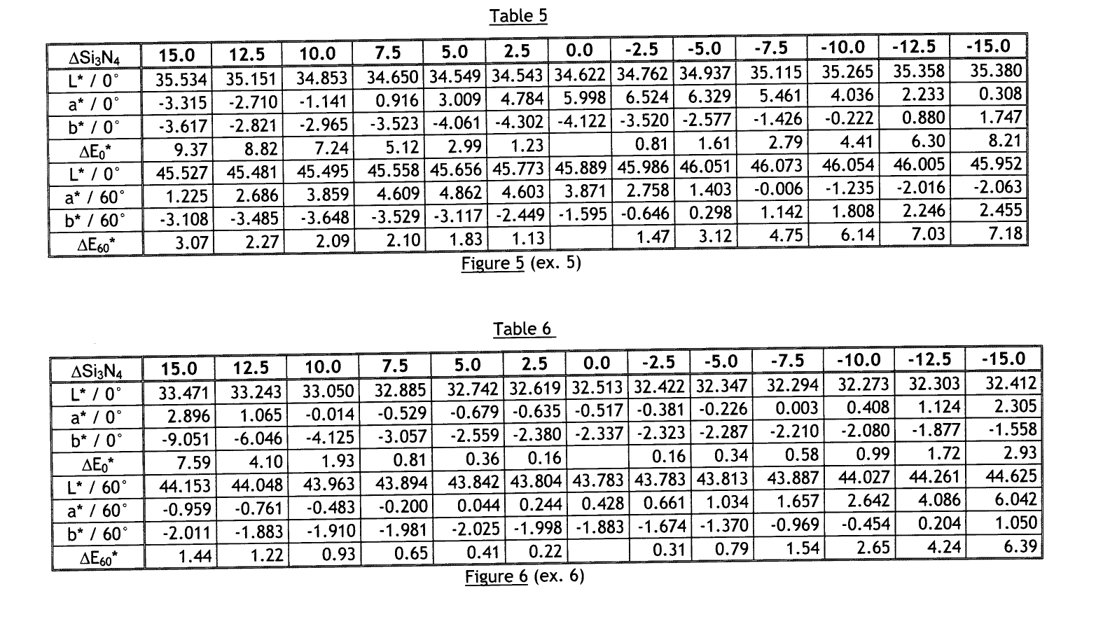

in FIG. 5, the optical characteristics for the examples 5;

in FIG. 6, the optical characteristics for the examples 6;

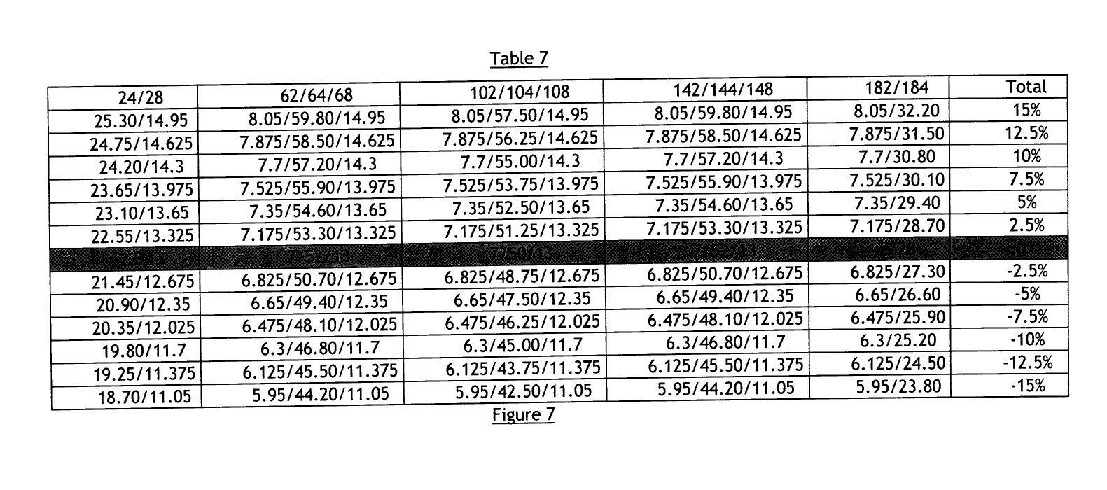

in FIG. 7, the variation in color as a function of the variation in the total thickness of silicon nitride for examples 3 and 4; and

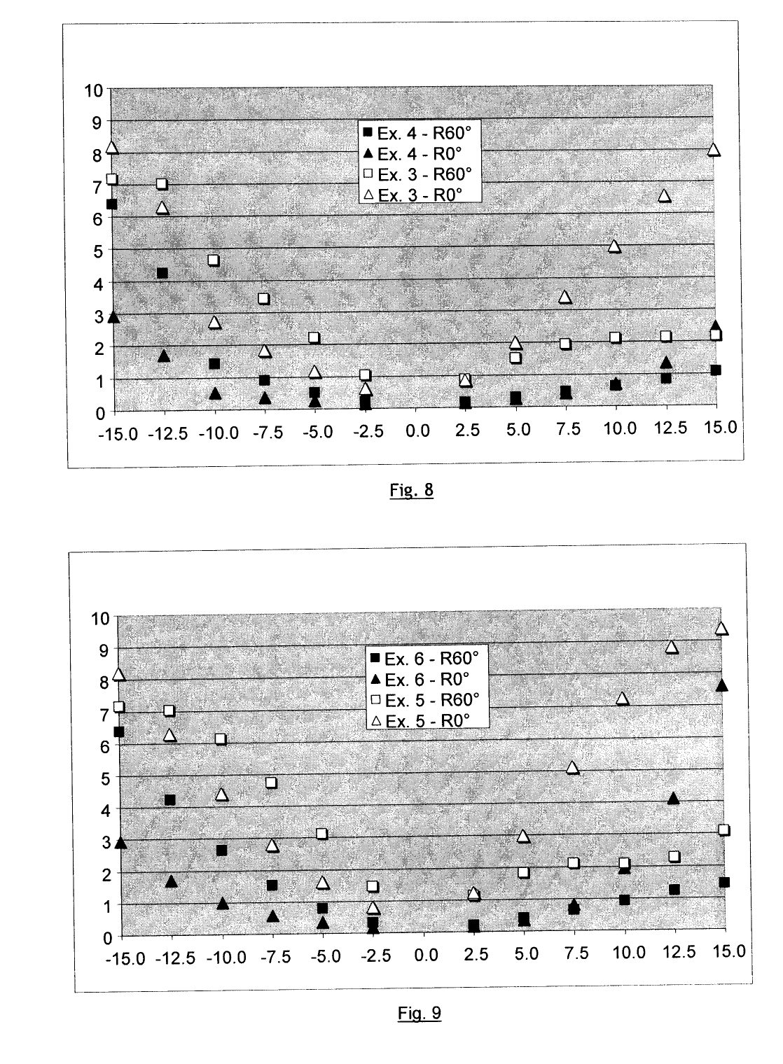

in FIG. 8, the variation in color is a function of the variation in the total thickness of the antireflection coating for examples 5 and 6.

In FIGS. 1 and 2, the proportions between the thicknesses of the various layers are not rigorously respected in order to facilitate the reading thereof.

FIG. 1 illustrates a multilayer structure having three functional layers 40, 80, 120, this structure being deposited on a transparent glass substrate 10.

Each functional layer 40, 80, 120 is positioned between two antireflection coatings 20, 60, 100, 140, so that the first functional layer 40 starting from the substrate is positioned between the antireflection coatings 20, 60; the second functional layer 80 is positioned between the antireflection coatings 60, 100 and the third functional layer 120 is positioned between the antireflection coatings 100, 140.

These antireflection coatings 20, 60, 100, 140 each comprise at least one dielectric layer 24, 26, 28; 62, 64, 66, 68; 102, 104, 106, 108; 142, 144.

Optionally, on one side each functional layer 40, 80, 120 may be deposited on an underblocker coating 35, 75, 115 positioned between the subjacent antireflection coating and the functional layer and on the other side each functional layer may be deposited directly beneath an overblocker coating (not illustrated) positioned between the functional layer and the superjacent antireflection coating.

In FIG. 1 it is observed that the multilayer terminates with an optional protective layer 200, in particular based on an oxide, especially that is sub-stoichiometric in oxygen.

According to the invention, the thicknesses of the functional layers 40, 120 located at the two extremities of the multilayer having three functional layers are both identical but are different from the thickness of the central functional layer 80.

FIG. 2 illustrates a multilayer structure having four functional layers 40, 80, 120, 160 this structure being deposited on a transparent glass substrate 10.

Each functional layer 40, 80, 120, 160 is positioned between two antireflection coatings 20, 60, 100, 140, 180, so that the first functional layer 40 starting from the substrate is positioned between the antireflection coatings 20, 60; the second functional layer 80 is positioned between the antireflection coatings 60, 100; the third functional layer 120 is positioned between the antireflection coatings 100, 140; and the fourth functional layer 160 is positioned between the antireflection coatings 140, 180.

These antireflection coatings 20, 60, 100, 140, 180, each comprise at least one dielectric layer 24, 26, 28; 62, 64, 66, 68; 102, 104, 106, 108; 144, 146, 148; 182, 184.

Optionally, on one side each functional layer 40, 80, 120, 160 may be deposited on an underblocker coating 35, 75, 115, 155, positioned between the subjacent antireflection coating and the functional layer and on the other side each functional layer may be deposited directly beneath an overblocker coating (not illustrated) positioned between the functional layer and the superjacent antireflection coating.

In FIG. 2 it is observed that the multilayer terminates with an optional protective layer 200, in particular based on an oxide, especially that is sub-stoichiometric in oxygen.

According to the invention, the thicknesses of the two functional layers 40, 160 furthest from the center of symmetry of the multilayer having four functional layers are both identical and the thicknesses of the two functional layers 80, 120 closest to the center of symmetry are both identical while being different from the two functional layers 40, 160 furthest from the center of symmetry of the multilayer.

A numerical simulation of multilayers having four functional layers was firstly carried out (examples 3 to 6 below), then a thin-film multilayer was actually deposited in order to validate these simulations, example 8.

Table 1 below illustrates the physical thicknesses, in nanometers, of each of the layers from examples 1 and 2:

TABLE 1

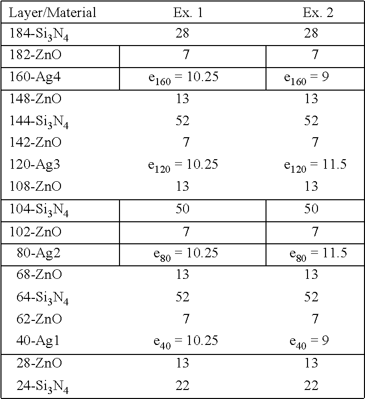

As can be seen in this table, for the counterexample 1, the four functional layers Ag1/40, Ag2/80, Ag3/120 and Ag4/160 all have the same thicknesses: e₄₀=e₈₀=e₁₂₀=e₁₆₀=10.25 nm.

For example 2 according to the invention, there is a central symmetry in the distribution of the thickness of the functional layers starting from the gray box without all the layers having the same thickness: the two functional layers closest to this center of symmetry, the layers Ag2/80 and Ag3/120 have the same thickness, respectively e₈₀=e₁₂₀=11.5 nm and the two functional layers furthest from this center of symmetry, the layers Ag1/40 and Ag4/160 have the same thickness, respectively e₄₀=e₁₆₀=9 nm and this thickness of the functional layers furthest from the center of symmetry is lower than the thickness of the two functional layers closest to the center of symmetry.

The sum of the thicknesses of all the functional layers from example 2 is identical to the sum of the thickness of all the functional layers from example 1: e₄₀+e₈₀+e₁₂₀+e₁₆₀ from example 1=e₄₀+e₈₀+e₁₂₀+e₁₆₀ from example 2=41 nm.

These two examples have the same functional layer total thickness, they have the same surface resistivities and the same energy reflection and energy transmission characteristics.

Next, a modification of the thickness of certain antireflection layers was simulated using COAT software distributed by W. Theiss.

In a first double series of simulations, only the thickness of the antireflection coatings made of Si₃N₄: 24, 64, 104, 144 and 184 from examples 1 and 2, was modified.

A series of examples 3 was carried out that was based on the structure of the functional layers from example 1 by modifying the thicknesses of the antireflection layers made of Si₃N₄: 24, 64, 104, 144 and 184, and a series of examples 4 was carried out that was based on the structure of the functional layers from example 2 by modifying the thicknesses of the antireflection layers made of Si₃N₄: 24, 64, 104, 144 and 184.

Table 2 below summarizes the simulated thicknesses, in nm, and also, in the last column, the total positive or negative thickness percentage for examples 3 and 4 relative to the total thickness of Si₃N₄ from the reference example (example 1 and example 2) shown in gray at the center of this table.

TABLE 2

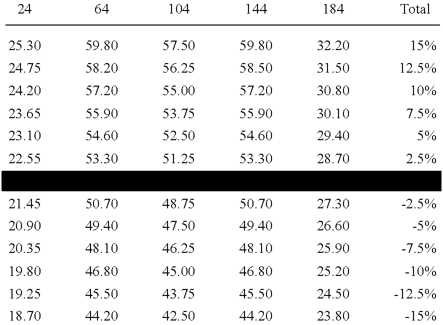

For example 3, the values in the La*b* colorimetric measurement system which were obtained at 0° (that is to say perpendicular to the substrate) and at 60° (that is to say at 60° relative to the perpendicular to the substrate) are presented in table 3 in FIG. 3 and for example 4, the values which were obtained in the same system are presented in table 4 in FIG. 4.

The color change values ΔE₀* and ΔE₆₀* presented in table 3 are illustrated in FIG. 8 for the values measured at 0° by unfilled triangles and for the values measured at 60° by unfilled squares and the color change values ΔE₀* and ΔE₆₀* presented in table 4 are illustrated in FIG. 8 for the values measured at 0° by filled triangles and for the values measured at 60° by filled squares.

This FIG. 8 clearly shows that for a given total thickness variation of antireflection layers, when the functional layers are distributed within the multilayer according to the invention (ex. 4) the color change values both at 0° and at 60° are smaller than when the functional layers are all of the same thickness within the multilayer (ex. 3). Such an effect may also be displayed by other simulations at other angles of observation.

Moreover, FIG. 8 shows that even when the total thickness variation of antireflection layers increases greatly (for example 12.5% or 15% relative to the nominal), the color change values both at 0° and at 60° are smaller when the functional layers are distributed within the multilayer according to the invention (ex. 4) than when the functional layers are all of the same thickness within the multilayer (ex. 3). Such an effect may also be displayed by other simulations at other angles of observation.

In a second double series of simulations, the thickness of the antireflection layers made of Si₃N₄: 24, 64, 104, 144 and 184 and the thickness of the antireflection layers made of ZnO: 28, 62, 68, 102, 108, 142, 148 and 182 were modified.

A series of examples 5 was carried out that was based on the structure of the functional layers from example 1 by modifying the thicknesses of the antireflection layers made of Si₃N₄: 24, 64, 104, 144, 184 and the thickness of the antireflection layers made of ZnO: 28, 62, 68, 102, 108, 142, 148, 182 and a series of examples 6 was carried out that was based on the structure of the functional layers from example 2 by modifying the thicknesses of the antireflection layers made of Si₃N₄: 24, 64, 104, 144, 184 and the thickness of the antireflection layers made of ZnO: 28, 62, 68, 102, 108, 142, 148, 182.

For example 5, the values in the La*b* colorimetric measurement system which were obtained at 0° (that is to say perpendicular to the substrate) and at 60° (that is to say at 60° relative to the perpendicular to the substrate) are presented in table 5 in FIG. 5 and for example 6, the values which were obtained in the same system are presented in table 6 in FIG. 6.

Table 7 in FIG. 7 summarizes the simulated thicknesses, in nm, of the layers of each of the five antireflection coatings in the first five columns and also, in the last column, the total positive or negative thickness percentage relative to the total thickness of Si₃N₄ and of ZnO of the reference example (example 1 and example 2) shown in gray at the center of this table.

The values presented in table 5 are illustrated in FIG. 9 for the values measured at 0° by unfilled triangles and for the values measured at 60° by unfilled squares and the values presented in table 6 are illustrated in FIG. 9, for the values measured at 0° by filled triangles and for the values measured at 60° by filled squares.

The observations for this FIG. 9 are similar to those made for FIG. 8.

FIG. 9 clearly shows that for a given total thickness variation of the antireflection layers, when the functional layers are distributed within the multilayer according to the invention (ex. 6) the color change values both at 0° and at 60° are smaller than when the functional layers are all of the same thickness within the multilayer (ex. 5).

Moreover, FIG. 9 shows that even when the total thickness variation of the antireflection layers increases greatly (for example 12.5% or 15% relative to the nominal), the color change values both at 0° and at 60° are smaller when the functional layers are distributed within the multilayer according to the invention (ex. 6) than when the functional layers are all of the same thickness within the multilayer (ex. 5).

Example 8 which was carried out has a structure similar to that of example 2, and in particular a distribution of the thickness of the functional layers which is identical to that of example 2; only the composition of the first four antireflection coatings changes, without however the total optical thickness of each of these antireflection coatings really changing.

Table 8 below summarizes the physical thicknesses, in nanometers, of each of the layers from example 8:

TABLE 8

| Layer/Material | Ex. 8 |
|---|---|
| 184 - Si₃N₄ | 28 |
| 182 - ZnO | 7 |
| 160 - Ag4 | 9 |
| 148 - ZnO | 7 |
| 146 - SnZnO | 6 |
| 144 - Si₃N₄ | 52 |
| 142 - ZnO | 7 |
| 120 - Ag3 | 11.5 |
| 108 - ZnO | 7 |
| 106 - SnZnO | 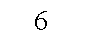 |
| 104 - Si₃N₄ | 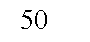 |
| 102 - ZnO | 7 |
| 80 - Ag2 | 11.5 |
| 68 - ZnO | 7 |
| 66 - SnZnO | 6 |
| 64 - Si₃N₄ | 52 |
| 62 - ZnO | 7 |
| 40 - Ag1 | 9 |
| 28 - ZnO | 7 |
| 26 - SnZnO | 6 |
| 24 - Si₃N₄ | 22 |

In this example, which is in accordance with the teaching of International Patent Application No. WO 2007/101964, each antireflection coating subjacent to a functional layer comprises a dielectric layer based on silicon nitride and at least one non-crystalline smoothing layer made of a mixed oxide, in this case a mixed oxide of zinc and tin which may be doped with antimony (deposited from a metallic target constituted of 65:34:1 weight ratios respectively for Zn:Sn:Sb), said smoothing layer being in contact with said superjacent wetting layer based on zinc oxide.

In this multilayer, the wetting layers 28, 68, 108, 148, made of aluminum-doped zinc oxide ZnO:Al (deposited from a metallic target constituted of zinc doped with 2 wt % of aluminum) make it possible to improve the crystallization of the silver functional layers 40, 80, 120, 160 which improves their conductivity; this effect is accentuated by the use of the amorphous SnZnOₓ:Sb smoothing layers 26, 66, 106, 146 which improve the growth of the superjacent wetting layers and therefore of the superjacent silver layers.

The layers made of silicon nitride are made of Si₃N₄ doped with 10 wt % of aluminum.

This multilayer furthermore has the advantage of being toughenable.

This substrate was deposited on a 2.1 mm transparent glass pane and after the deposition of the multilayer, this substrate was combined with a 0.76 mm sheet of PVB then with a second 2.1 mm transparent glass pane in order to form a laminated glazing unit.

Table 9 below summarizes the characteristics of this example 8. The data for the substrate alone before any treatment are indicated in the “BHT” line. The data for the substrate alone after an annealing heat treatment at 650° C. for 3 min are indicated in the “AHT” line. The data for the substrate integrated into the laminated glazing unit and without heat treatment are indicated in the “LG” line.

TABLE 9

| | R [Ohm/square] | R_{L} (%) | a*D65/2° | b*D65/2° | T_{L} (%) | A (%) |
|---|---|---|---|---|---|---|
| BHT | 1.2 | 7 | −1.9 | −1.5 | 72 | 21 |
| AHT | 0.9 | 7 | −3.0 | −0.5 | 76 | 16 |
| LG | — | 8 | −1.4 | −1.3 | 75 | 17 |

Due to the large total thickness of the silver layers (and therefore the low surface resistivity obtained) and also the good optical properties (in particular the light transmission in the visible spectrum), it is possible, moreover, to use the substrate coated with the multilayer according to the invention for producing a transparent electrode substrate.

This transparent electrode substrate may be suitable for an organic light-emitting device, in particular by replacing the silver nitride layer 184 from example 8 with a conductive layer (having, in particular, a resistivity of less than 10⁵ Ω.cm) and especially an oxide-based layer. This layer may be, for example, made of tin oxide or based on zinc oxide optionally doped with Al or Ga, or based on a mixed oxide and especially on indium tin oxide ITO, indium zinc oxide IZO, tin zinc oxide SnZnO that is optionally doped (for example with Sb, F). This organic light-emitting device may be used for producing an illumination device or a display device (screen).

Generally, the transparent electrode substrate may be suitable as a heated substrate for a heated glazing unit and in particular a heated laminated windshield.

It may also be suitable as a transparent electrode substrate for any electrochromic glazing, any display screen, or else for a photovoltaic cell and especially for a front face or a rear face of a transparent photovoltaic cell.

The process is preferably not meant to be used for manufacturing substrates for a screen filter.

The present invention is described in the aforegoing by way of example. It is understood that a person skilled in the art is capable of carrying out various variants of the invention without however departing from the scope of the patent as defined by the claims.

1. A process for manufacturing at least one substrate, each provided with a thin-film multilayer, the process comprising:
depositing the thin-film multilayer by a vacuum sputtering technique onto the at least one substrate,
wherein the multilayer comprises an alternation of “n” metallic functional layers, and of “(n+1)” antireflection coatings, with n being an integer ≧3,
wherein each antireflection coating comprises at least one antireflection layer, so that each functional layer is positioned between two antireflection coatings,
wherein the multilayer is such that thicknesses of at least two of the functional layers are different and thicknesses of the functional layers have a symmetry within the multilayer relative to a center of the multilayer,
wherein the thicknesses of at least one antireflection layer of at least one antireflection coating of at least two thin-film multilayers of a set of substrates are different and exhibit a variation between ±2.5% and ±20%, and
wherein a difference in color in reflection on a substrate side between the two substrates at 0° (ΔE₀*) is close to zero and the color in reflection on the substrate side between the two substrates at 60° (ΔE₆₀*) is close to zero.

2. The process of claim 1, wherein the multilayer comprises three functional layers alternated with four antireflection coatings, and
the thicknesses of the functional layers located at the two extremities of the multilayer are both identical but are different from a thickness of the central functional layer.

3. The process of claim 2, wherein a thickness of the functional layer at the center of the symmetry is greater than the thickness of the two other functional layers furthest from the center of symmetry.

4. The process of claim 1, wherein the multilayer comprises four functional layers alternated with five antireflection coatings, and
thicknesses of the two functional layers furthest from the center of symmetry are both identical and the thicknesses of the two functional layers nearest to the center of symmetry are both identical.

5. The process of claim 4, wherein the thickness of the two functional layers closest to the center of symmetry is greater than the thickness of the two functional layers furthest from the center of symmetry.

6. The process of claim 4, wherein the thickness of the two functional layers closest to the center of symmetry is smaller than the thickness of the two functional layers furthest from the center of symmetry.

7. The process of claim 1 wherein the antireflection coatings each comprise at least one layer comprising silicon nitride, optionally doped with at least one other element.

8. The process of claim 1, wherein the last layer of each antireflection coating subjacent to a functional layer is a wetting layer comprising an oxide, optionally doped with at least one other element.

9. The process of claim 8, wherein at least one antireflection coating subjacent to a functional layer comprises at least one non-crystalline smoothing layer comprising a mixed oxide, said smoothing layer being in contact with a crystalline superjacent wetting layer.

10. A set of substrates, manufactured by the process of claim 1, wherein thicknesses of at least one antireflection layer of at least one antireflection coating of at least two thin-film multilayers of a set of substrates are different and exhibit a variation between ±2.5% and ±20%, and a difference in color in reflection on a substrate side between the two substrates at 0° (ΔE₀*) is close to zero and the color in reflection on the substrate side between the two substrates at 60° (ΔE₆₀*) is close to zero.

11. A set of glazing units, each glazing unit of which comprises at least one substrate manufactured by the process of claim 1, wherein thicknesses of at least one antireflection layer of at least one antireflection coating of at least two thin-film multilayers of the set of substrates are different and exhibit a variation between ±2.5% and ±20%, and a difference in color in reflection on a substrate side between the two glazing units at 0° (ΔE₀*) is close to zero and the color in reflection on the substrate side between the two glazing units at 60° (ΔE₆₀*) is close to zero.

12. The set of claim 11, combined with at least one other substrate and optionally a multiple glazing unit as a double-glazing or triple-glazing or laminated-glazing, or a laminated glazing comprising unit for the electrical connection of the thin-film multilayer in order to make it possible to produce a heated laminated glazing, said substrate bearing the multilayer optionally being at least one of curved and toughened.

13. The process of claim 1, wherein the at least one substrate is transparent glass.

14. The process of claim 1, wherein at least one of the “n” metallic functional layers comprises silver.

15. The process of claim 1, wherein at least one of the “n” metallic functional layers comprises a metal alloy comprising silver.

16. The process of claim 1, wherein the “n” metallic functional layers comprise silver or a metal alloy comprising silver.

17. The process of claim 1, wherein the thicknesses of the at least one antireflection layer of at least one antireflection coating of at least two thin-film multilayers of a set of substrates are different and exhibit a variation between ±2.5% and ±15%.

18. The process of claim 7, wherein the wetting layer is doped with aluminum.

19. The process of claim 7, wherein the last layer of each antireflection coating subjacent to a functional layer is a wetting layer comprising zinc oxide, optionally doped with at least one other element.

20. The process of claim 19, wherein the wetting layer is doped with aluminum.
